(19) United States
(12) Patent Application Publication
(10) Pub. No.: US 2011/0056534 A1
(43) Pub. Date: Mar. 10, 2011

(54) SEMITRANSPARENT PHOTOVOLTAIC FILM

(75) Inventors: Jau-Min Ding, Taipei City (TW); Je-Ping Hu, Hsinchu City (TW); Chun-Chao Chen, Hsinchu City (TW)

(73) Assignee: INDUSTRIAL TECHNOLOGY RESEARCH INSTITUTE, Hsinchu (TW)

(21) Appl. No.: 12/613,509

(22) Filed: Nov. 5, 2009

(30) Foreign Application Priority Data
Sep. 7, 2009 (TW) 98130062

(51) Int. Cl. H01L 31/042

(52) U.S. Cl. 136/244

(57) ABSTRACT

A semitransparent photovoltaic film is provided, including a flexible substrate that integrates a plurality of first and second planar portions, and a plurality of photovoltaic cells. An angle is also included correspondingly between the first and the second planar portions. The photovoltaic cells are formed on a plurality of surfaces of the first planar portions of the flexible substrate. According to a design of the semitransparent photovoltaic film, most directly incident sunlight is absorbed and then converted into electricity, and most of the lights progressing horizontally or on a upward slant can pass through the film, thereby achieving the transparent visual effect.

### CROSS-REFERENCE TO RELATED APPLICATION

This application claims the priority benefit of Taiwan application serial no. 98130062, filed on Sep. 7, 2009. The entirety of the above-mentioned patent application is hereby incorporated by reference herein and made a part of specification.

### BACKGROUND

1. Technical Field

The disclosure relates to a light, thin, and flexible semitransparent photovoltaic film.

2. Description of Related Art

Solar energy is one of the renewable energy sources free of pollution. While crisis caused by the usage of fossil fuels such as pollutions, global warming, and shortage of supply emerge worldwide, attentions have been focused on effective utilize of solar energy. Being capable of transferring solar energy into electrical energy, the photovoltaics have received considerable effort to make this technology grow in global energy markets.

However, the primary factor impeding widespread utilization of photovoltaics is its relatively high cost of energy generation when compared with other electricity generation techniques. Therefore, many researchers have sought to decrease the cost by developing new materials and fabrication techniques. Many research studies have shown that a flexible PV may have the advantages of ease of storage and rapid roll to roll mass production due to its flexibility. In addition, using of flexible substrate advantages the flexible photovoltaics to the property of high energy to weight ratio, thus it may be suitable for use as a portable energy source. Moreover, if the conversion efficiency and the product lifespan are sufficient, the flexible photovoltaics could also compete in applications of Building Integrated Photovoltaics-BIPV such as solar roofing and facade systems based on flexibility (a PV truly integrated into building materials) and on cost.

From a market standpoint, products possessing special applications often demand a high premium. For instance, if solar cells possess characteristics of light and flexibility, the profit would be increased when applying them to portable electronics. If a “semitransparent” flexible photovoltaics could be developed and new applications such as a heat resistance and electricity generating thin film could be explored, it is expectable that a specific market (i.e. photovoltaic adiabatic paper) would be created and easily separated from other conventional photovoltaics by such particular product characteristics.

Recent researches, for example U.S. Pat. Nos. 6,180,871, 6,320,117, and 6,509,204 have proposed transparent solar cell structures constructed by using polycrystalline silicon thin films and transparent positive/negative electrodes. However, such proposals suffer not only high fabrication cost on polycrystalline silicon thin film forming, but also serious color shift of transmitting light. Moreover, a decrease in light absorption is not the only factor contributing to device efficiency loss. Other factors causing further device deterioration along with efficiency loss include not having a multiple reflecting surface structure while having thinner absorption layers.

Therefore, other researchers have suggested using high band gap (i.e. no visible light absorption) semiconductor materials (e.g. metal oxides mostly) to fabricate transparent solar cells. For example, US Patent Publication No. 2008/0053518 disclosed this technique to obtain non color shifting transparent solar cells. However, 51.8% of solar radiation lies in visible region, while only approximately 6% lies in the ultraviolet part absorbed by the aforementioned proposal. Hence, the decrease of solar power absorption of the high band gap semiconductor layer of the device results in deficient electric power generation.

In addition, other works, for example U.S. Pat. Nos. 4,137,098, 5,221,363, and 5,258,076, as well as US Patent Publication No. 2008/0257403 have proposed the novel design of solar window structures involving assembling PV components as strip-like horizontal slats into a module. Each slat in the module has an angle with the vertical surface, so that it can shield sunlight and generate electricity at the same time; however, having an enormous volume along with a poor aesthetic appearance and complex installation process, this semitransparent solar window is seldom applied in modern building constructions.

### SUMMARY

The disclosed semitransparent photovoltaic film comprises a flexible substrate integrating a plurality of first planar portions and a plurality of second planar portions, and a plurality of photovoltaic cells. The second planar portions are coupled with the first planar portions to form an angle. The photovoltaic cells are formed on a plurality of surfaces of the first planar portions of the flexible substrate.

Another embodiment of the semitransparent photovoltaic film comprises a support substrate, a flexible substrate, and a plurality of photovoltaic cells. The aforementioned first support substrate has a first zigzag surface. The aforementioned flexible substrate integrates a plurality of first planar portions and a plurality of second planar portions. The second planar portions are coupled with the first planar portions to form an angle. The photovoltaic cells are formed on a surfaces of each of the first planar portions of the flexible substrate. The flexible substrate is further laminated on the first support substrate to form the photovoltaic film, on condition that a first planar surface is laminated on the first zigzag surface.

### BRIEF DESCRIPTION OF THE DRAWINGS

The accompanying drawings are included to provide a further understanding of the embodiment, and are incorporated in and constitute a part of this specification. The drawings illustrate embodiments of the embodiment and, together with the description, serve to explain the principles of the embodiment.

FIG. 1 is a schematic three-dimensional view of a semitransparent photovoltaic film in accordance with a first embodiment.

FIG. 2 illustrates an alternative embodiment to the first embodiment.

FIG. 3 is a schematic three-dimensional view of a semitransparent photovoltaic film in accordance with a second embodiment.

FIG. 4 is a schematic three-dimensional view of a semitransparent photovoltaic film in accordance with a third embodiment.

FIG. 5 is a schematic three-dimensional view of a semitransparent photovoltaic film in accordance with a fourth embodiment.

FIG. 6A illustrates a flexible substrate of the semitransparent photovoltaic film in accordance with some embodiments.

FIG. 6B illustrates a support substrate in accordance with some embodiments.

FIG. 6C is a schematic diagram illustrating a rapid integration process of the flexible substrate depicted in FIG. 6A and the support substrate depicted in FIG. 6B.

FIGS. 7A-7B are schematic diagrams illustrating another fabrication process of the semitransparent photovoltaic film in accordance with some embodiments.

FIG. 8 is an exploded three-dimensional view of a semitransparent photovoltaic film in accordance with a fifth embodiment.

FIG. 9 is a diagram illustrating a relation between sunlight exposure and the semitransparent photovoltaic film in accordance with some embodiments.

FIG. 10 is a diagram illustrating a relationship of sunlight collection efficiency (solid line) and horizontal light transmittance (dotted line) versus the α angle.

### DESCRIPTION OF EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

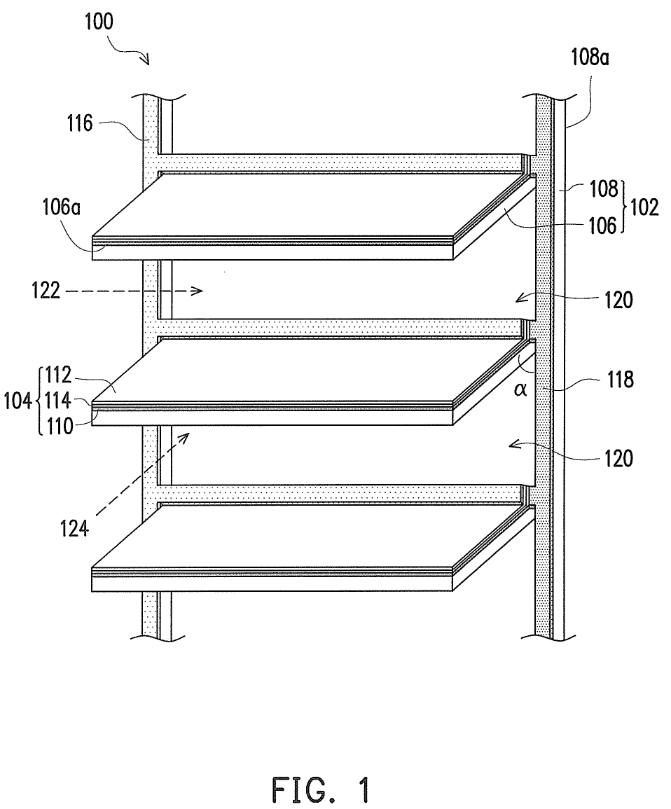

FIG. 1 is a schematic three-dimensional view of a semitransparent photovoltaic film in accordance with a first embodiment.

Referring to FIG. 1, a semitransparent photovoltaic film 100 of the embodiment includes a flexible substrate 102 and a plurality of photovoltaic cells 104. The flexible substrate 102 integrates a plurality of first planar portions 106 and a plurality of second planar portions 108. Moreover, the second planar portions 108 and the first planar portions 106 are coupled to each other so as to form an angle α. In other words, the first planar portions 106 and the second planar portions 108 are formed on the aforementioned flexible substrate 102. For example, a coupling side is formed by a side of the first planar portions 106 for coupling to the second planar portions 108, so as to separate the other sides of the first planar portions 106 from the second planar portions 108. Thereafter, by using the coupling side as an axis, the first planar portions 106 and the second planar portions 108 form the above-mentioned angle. In addition, the second planar portions 108 may form a rectangular frame structure having a plurality of first planar portions 106 configured therein. In the embodiments described hereinafter, the second planar portions are similar. The first planar portions 106 can be rectangular. Using FIG. 1 as an example, the first planar portions 106 are formed by each of the photovoltaic cells 104 arranged as a parallel fan and assembled in the second planar portions 108.

Referring again to FIG. 1, the flexible substrate 102 can be a light transmitting or an opaque substrate. The transparent substrate is plastic or glass, or the like, for example. Moreover, the opaque substrate is a metal substrate (e.g., aluminum substrate, stainless steel, molybdenum substrate, or the like) or an opaque plastic substrate (e.g., polyimide substrate or the like). The photovoltaic cells 104 are formed on the surfaces 106a of the first planar portions 106 of the flexible substrate 102. Depending on different incident light directions, the structure of a photovoltaic cell can be categorized into a superstrate structure and a substrate structure. The superstrate structure starts with coating a transparent electrode (e.g., transparent conductive oxide (TCO)) under the substrate, and thereafter coating the photoelectric conversion cell and the opaque electrode (e.g., metal conductive layer) in turns. On the other hand, the substrate structure starts with coating the opaque electrode above the substrate, then coating in turns the photoelectric conversion cell and finally the transparent electrode. Since light is incident on the photovoltaic cells 104 side, the above-described photovoltaic cells 104 are a substrate structure photovoltaic cell. Therefore, the flexible substrate 102 can be a light transmitting substrate or an opaque substrate. The photovoltaic cells 104 include an opaque electrode 110, a light transmitting electrode 112 disposed on the opaque electrode 110, and a photoelectric conversion cell 114 disposed between the opaque electrode 110 and the transparent electrode 112.

Continuing reference to FIG. 1, the material of the aforementioned opaque electrode 110 includes metals (e.g., aluminum, silver, etc.) or alloys (e.g., silver-aluminum alloy etc.). For instance, the photoelectric conversion cell 114 is an amorphous silicon thin film photovoltaic cell, a CuInGaSe₂ (CIGS) thin film photovoltaic cell, an organic photovoltaic cell, a CdTe thin film photovoltaic cell, or the like. For example, the photoelectric conversion cell 114 can be an amorphous silicon thin film photovoltaic cell formed by buffer layers (e.g., ZnO), n-i-p amorphous layers, and transparent conductive oxide (TCO) materials (e.g., JO, TO, ZO, ITO, or IZO). Additionally, the photoelectric conversion cell 114 can also be a CIGS thin film photovoltaic cell formed by molybdenum electrodes and materials such as CIGS, CdS (or other suitable materials) and ZnO. Furthermore, the photoelectric conversion cell 114 can also be an organic photovoltaic cell formed by buffer layers, polymer blends or p/n bilayers, and buffer layer and TCO materials (e.g., JO, TO, ZO, ITO, or IZO). The photoelectric conversion cell 114 can also be a CdTe thin film photovoltaic cell formed by CdTe, CdS, and TCO materials (e.g., JO, TO, ZO, ITO, or IZO).

Referring again to FIG. 1, each of the second planar portions 108 has at least a light transmitting opening 120 to allow light to pass, when the flexible substrate 102 is an opaque substrate. Moreover, each of the second planar portions 108 can also have an adhesive surface 108a in order to widen an application surface of the semitransparent photovoltaic film 100. For instance, the semitransparent photovoltaic film 100 can be adhered to structures such as the outer windows of buildings. The outer windows can be a glass curtain (or wall), on which sunlight can be absorbed but the aesthetic appearance of the building is not affected. Since the semitransparent photovoltaic film 100 of the first embodiment can absorb sunlight incident from above while not obstructing a horizontal light 122 and a light beneath 124, the semitransparent photovoltaic film 100 visually appears transparent because the film can absorb most of the incident sunlight and further allow the horizontal light and the light underneath to penetrate.

Continuing reference to FIG. 1, the above-described semitransparent photovoltaic film 100 also has a plurality of conductive lines 116 and 118 formed on the flexible substrate 102. In order to increase conductivity, the conductive lines 116 are coupled to the light transmitting electrode 112 of each of the photovoltaic cells 104. Since two neighboring (i.e. located above and below each other) light transmitting electrodes 112 on the first planar portions 106 are coupled to each other through the conductive lines 116, and the opaque electrodes 110 are coupled to each other through the conductive lines 118, a parallel configuration coupling electrodes of the same polarity is formed.

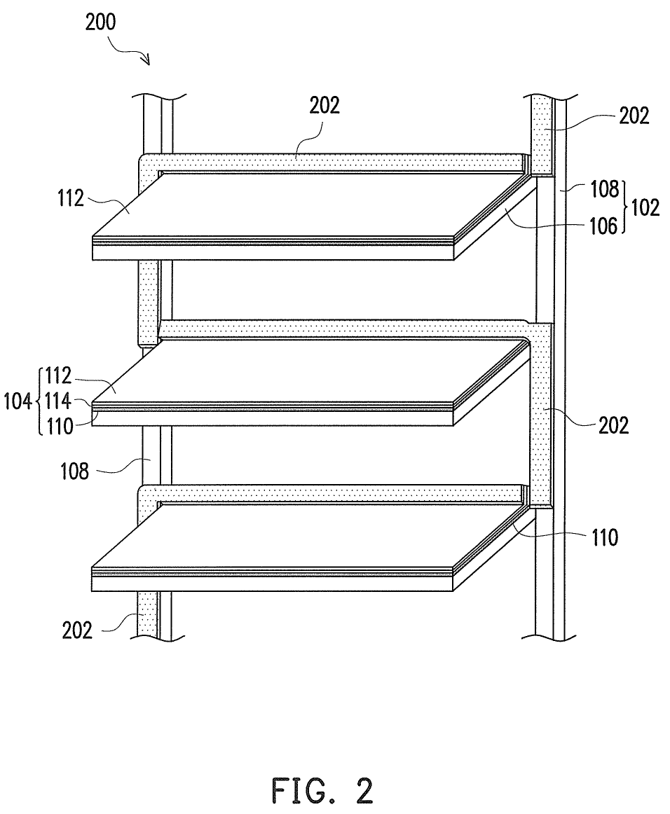

Besides, an alternative embodiment to the first embodiment is illustrated in FIG. 2. Except for the location of the conductive lines 202, the rest of the structure of a semitransparent photovoltaic film 200 depicted in FIG. 2 is the same as depicted in FIG. 1. In order to turn on the photovoltaic cells 104, the conductive lines 202 depicted in FIG. 2 are coupled to the light transmitting electrodes 112 of the photovoltaic cells 104 as well as the opaque electrodes 110 of the next one of the photovoltaic cells 104. Therefore, a serial configuration of opposite polarity electrodes can be formed.

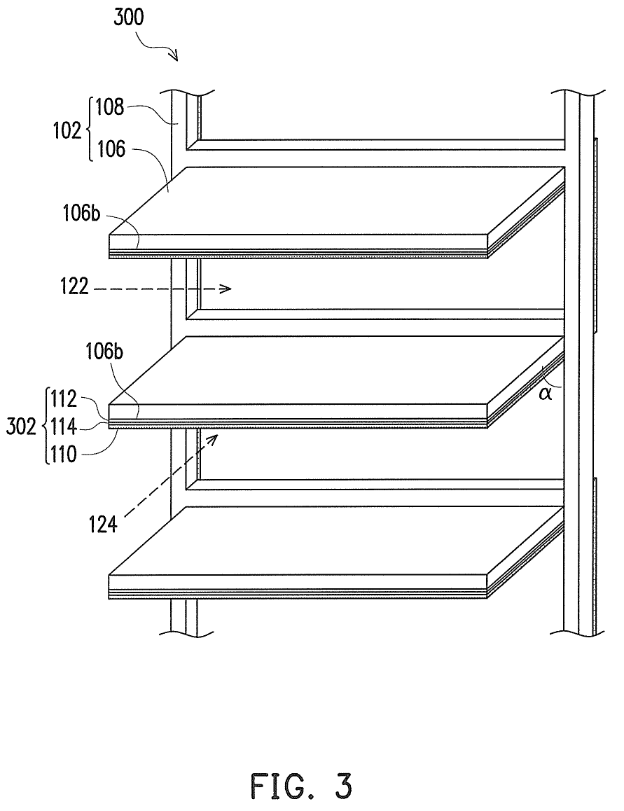

FIG. 3 is a schematic cross-sectional view illustrating a semitransparent photovoltaic film in accordance with a second embodiment. Same reference numerals as those according to the first embodiment are used to represent same components.

Referring to FIG. 3, a photovoltaic cell 302 in a semitransparent photovoltaic film 300 of the embodiment is a superstrate structure photovoltaic cell. The superstrate structure refers to light being incident on the substrate side. Therefore, a light transmitting substrate is required for the flexible substrate 102. If this design is adopted, the light transmitting electrodes 112, the photoelectric conversion cell 114, and the opaque electrode 110 are sequentially formed on the surfaces 106b of the first planar portions 106 of the flexible substrate 102 (light transmitting substrate). The second planar portions 108 and the first planar portions 106 are coupled to each other so as to form an angle α. Moreover, the horizontal light 122 and the light beneath 124 are not shielded. Most of the incident sunlight can be absorbed while further allowing the horizontal light and the light beneath to pass though the semitransparent photovoltaic film 300, thereby achieving a transparent visual effect. In addition, the photovoltaic cell 302 depicted in FIG. 3 uses the conductive lines 202 of FIG. 2 to form a serial configuration, although the disclosure is not limited thereto.

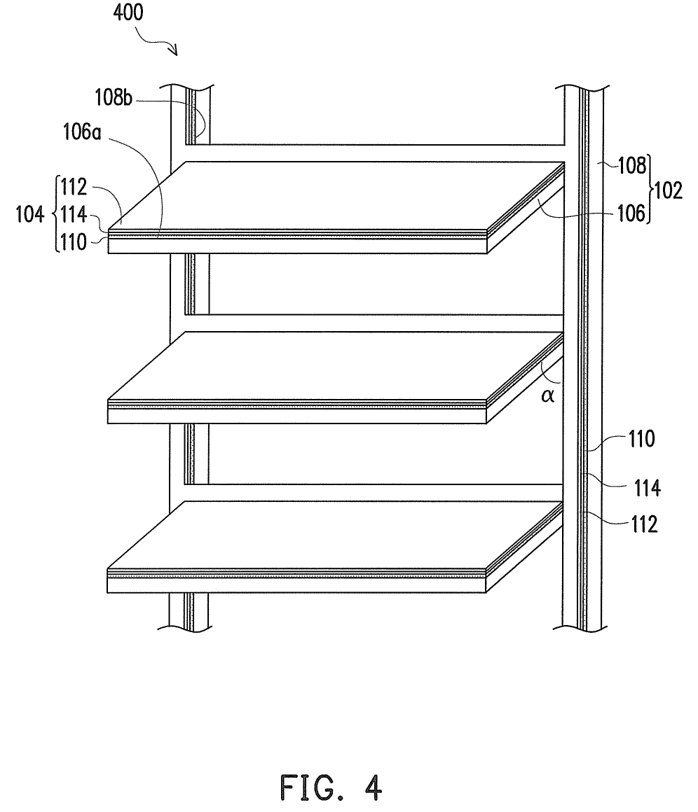

FIG. 4 is a schematic three-dimensional view illustrating a semitransparent photovoltaic film in accordance with a third embodiment. Same reference numerals as those according to the first embodiment are used to represent same components.

Referring to FIG. 4, a difference between a semitransparent photovoltaic film 400 of the embodiment and the semitransparent photovoltaic film 100 of the first embodiment is that extra conductive lines are not required (e.g., conductive lines 116 and 118 of FIG. 1 and conductive lines 202 of FIG. 2). By contrast, the opaque electrode 110, the photoelectric conversion cell 114, and the light transmitting electrode 112 are sequentially formed on the surface 106a of the first planar portions as well as a surface 108b of the second planar portions 108. Moreover, the opaque electrode 110 and the transparent electrode 112 on the surface 108b of the second planar portions 108 are used as conductive lines to directly couple the photovoltaic cells 104 on different first planar portions 106. Besides, the above-described photovoltaic cells 104 are substrate structure photovoltaic cells. Therefore, the flexible substrate 102 can be a light transmitting substrate or an opaque substrate.

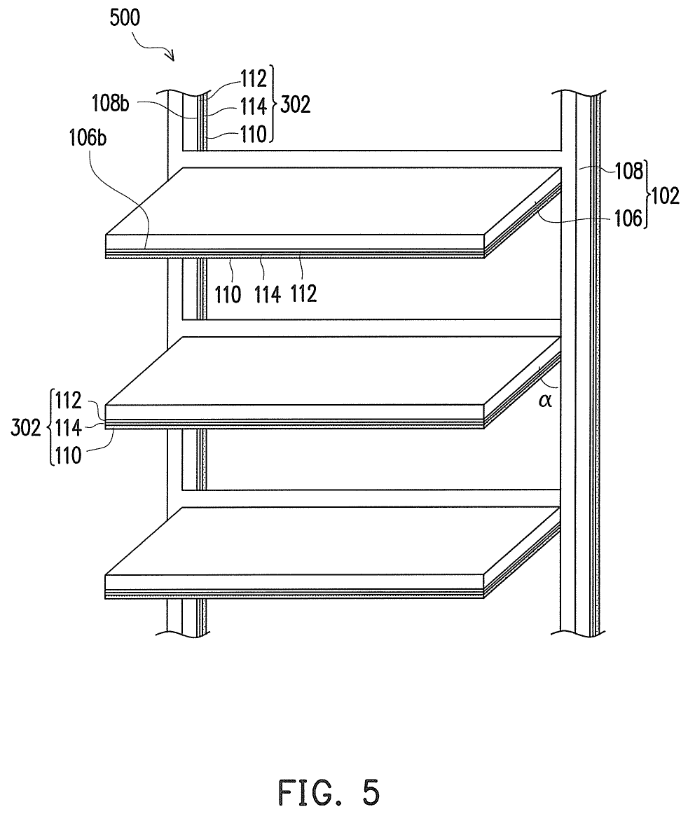

FIG. 5 is a schematic three-dimensional view illustrating a semitransparent photovoltaic film in accordance with a fourth embodiment. Same reference numerals as those according to the second embodiment are used to represent same components.

Referring to FIG. 5, a difference between a semitransparent photovoltaic film 500 of the embodiment and the semitransparent photovoltaic film 200 of the second embodiment is that extra conductive lines are not required (e.g., conductive lines 202 of FIG. 3). By contrast, the light transmitting electrode 112, the photoelectric conversion cell 114, and the opaque electrode 110 are sequentially formed and completely cover the surface 106a of the first planar portions as well as the surface 108b of the second planar portions 108. Moreover, the opaque electrode 110 and the transparent electrode 112 on the surface 108b of the second planar portions 108 are used as conductive lines to directly couple the photovoltaic cell 302 on different first planar portions 106.

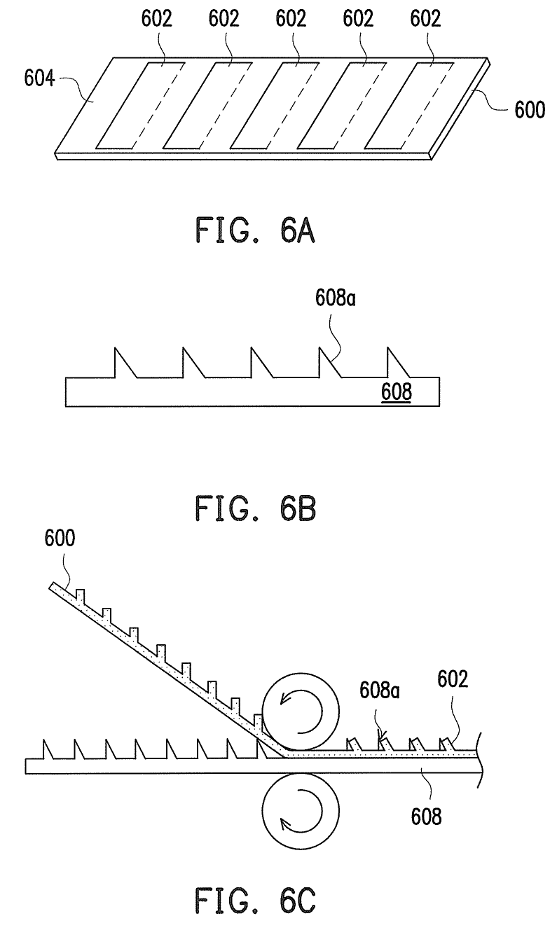

For fabrication of the above-described semitransparent photovoltaic film depicted in FIGS. 1-5, currently available techniques can be used. For example, as shown in FIG. 6A, a required photovoltaic cell (not shown) can be formed on a flexible substrate 600, and a plurality of planar sections 602 can be formed by laser cutting or mechanical cutting. Areas outside the first planar sections 602 form a plurality of second planar sections 604. The plastic molding of the flexible substrate can be formed by a heating process or a pressurizing process so that the semitransparent photovoltaic film depicted in FIGS. 1-5 is fabricated. Alternatively, as shown in FIG. 6A, by using an ultraviolet (UV) molding technique, a support substrate 608 including a zigzag surface 608a is fabricated. Thereafter, as shown in FIG. 6C, the flexible substrate 600 and the support substrate 608 can be rapidly integrated by using a roll to roll process.

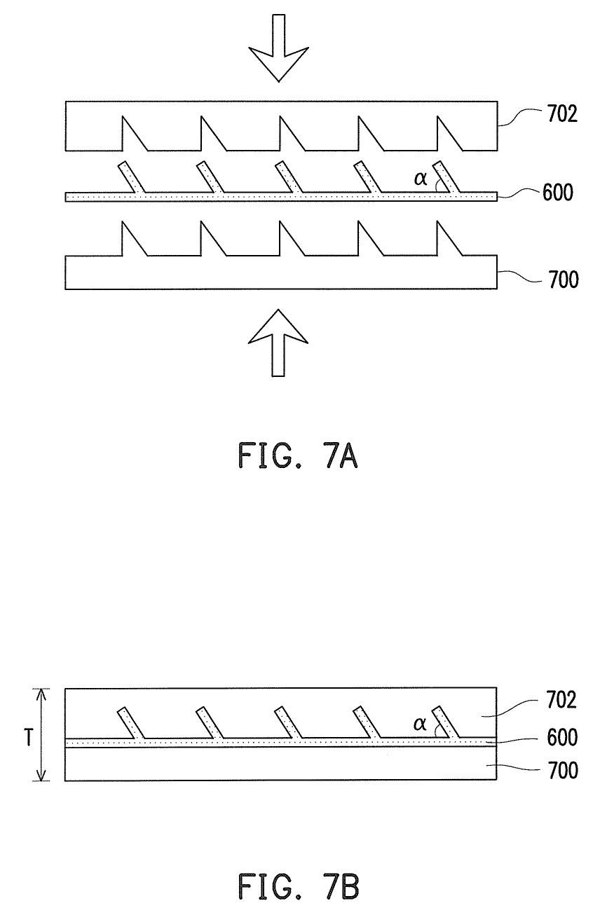

Another technique to fabricate the semitransparent photovoltaic film of the disclosure is illustrated in FIG. 7A-7B. In FIG. 7A, after the flexible substrate 600 is cut, the flexible substrate 600 is integrated with the plastic molded support substrates 700 and 702. As shown in FIG. 7B, after integration, a tightly encapsulated semitransparent photovoltaic film is formed. A total thickness T of the completed semitransparent photovoltaic film is between 1 mm and 15 mm.

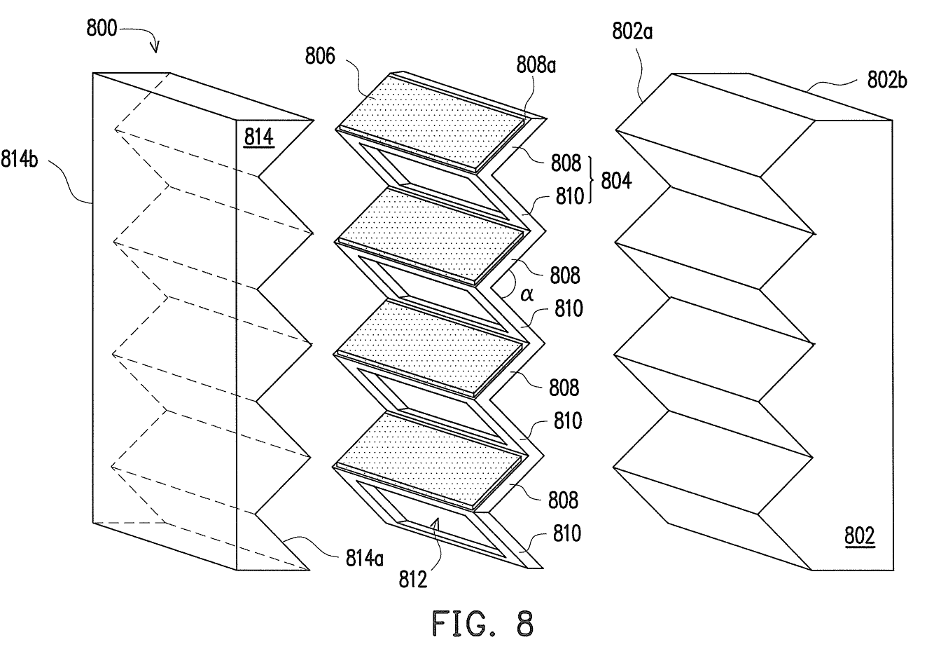

FIG. 8 is an exploded three-dimensional view of a semitransparent photovoltaic film in accordance with a fifth embodiment.

Referring to FIG. 8, a semitransparent photovoltaic film 800 of the embodiment includes a first support substrate 802, a flexible substrate 804, and a photovoltaic cell 806. The aforementioned first support substrate 802 has a first zigzag surface 802a. The flexible substrate 804 is laminated on the zigzag surface 802a of the first support structure 802. After lamination, the flexible substrate 804 of the fifth embodiment can have a zigzag shape allowing the flexible substrate 804 to be disposed on the zigzag surface 802a of the first support substrate 802. The aforementioned flexible substrate 804 integrates a plurality of first planar portions 808 and a plurality of second planar portions 810. The second planar portions 810 and the first planar portions 808 are adjacent and coupled to each other so as to form an angle α. By configuring the second planar portions 810 and the first planar portions 808 to indirectly couple to each other, a zigzag structure is formed. The photovoltaic cell 806 is formed on a surface 808a of the first planar portions 808 of the flexible substrate 804. For the material and the configuration of the flexible substrate 804 and the photovoltaic cell 806 of the embodiment, since points of reference can be directed to the above-described embodiments, no further description is provided hereinafter. Moreover, the first support substrate 802 of the embodiment further includes a first planar surface 802b opposing the first zigzag surface 802a. For example, the first planar surface 802b is an adhesive surface that helps to widen the application surface of the semitransparent photovoltaic film 800. By adhering the film to structures such as the outer windows of buildings, the aesthetic appearance of the buildings can be preserved while sunlight is absorbed. Moreover, each of the second planar portions 810 has at least a light transmitting opening 812 to allow light to penetrate, specifically when the flexible substrate 804 is an opaque substrate.

Besides, in the fifth embodiment, the aforementioned semitransparent photovoltaic film 800 further includes a second support substrate 814. The second support substrate has a second zigzag surface 814a complementing the first zigzag surface 802a of the first support substrate 802. Moreover, the flexible substrate 804 is laminated between the first zigzag surface 802a of the first support substrate 802 and the second zigzag surface 814a of the second support substrate 814. The second support substrate can also have a second planar surface 814b opposing the second zigzag surface 814a. Furthermore, the aforementioned second planar surface 814b is an adhesive surface, for example, that helps widen the application surface of the semitransparent photovoltaic film. In the embodiment of the disclosure, the above-described first support substrate 802 and the second support substrate 814 can be made of soft materials, such as plastic or glass. In addition, one of the first support substrate 802 or the second support substrate 814 is, for example, disposed on a light receiving surface of the semitransparent photovoltaic film 800 to be light transmitting.

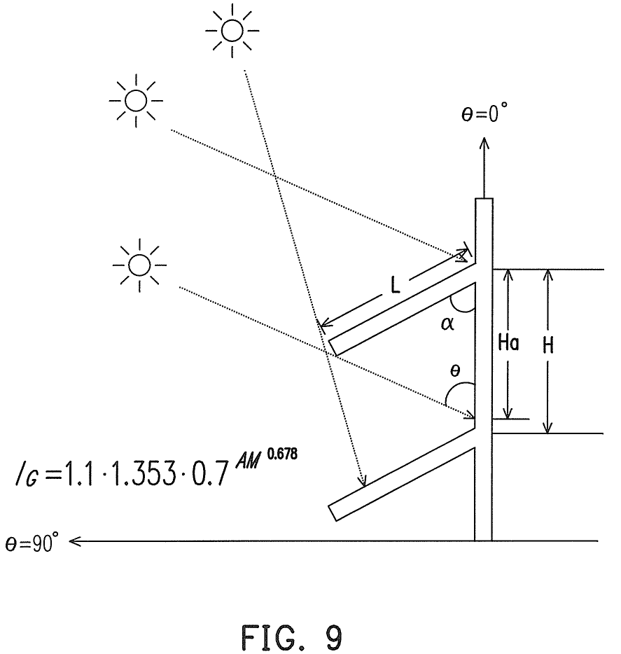

According to embodiments of the disclosure, the design principles for the semitransparent photovoltaic film need to consider the sunlight collection efficiency as well as the light transmittance. Note that the sunlight collection efficiency is defined as the fraction of sunlight incident on the first planar portions when sun moves from the horizon to the zenith. FIG. 9 illustrates the relationship between incident sunlight and the semitransparent photovoltaic film as embodied herein. The parameter L represents the length of the first planar portions, H represents the vertical distance between two first planar portions, Ha represents the length of the shadow cast by the first planar portions on the second planar portions (vertical plane), α represents the angle formed between the first planar portions and the second planar portions, and θ represents the angle between the incident light and the second planar portions.

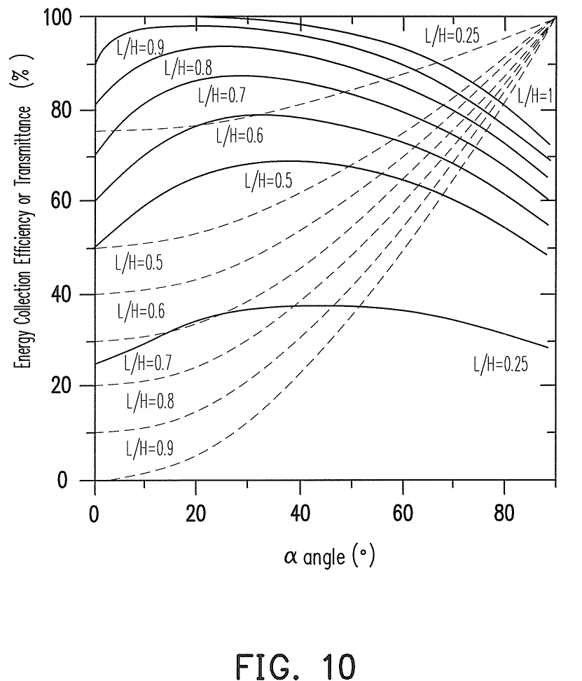

FIG. 10 exhibits the calculated results of the sunlight collection efficiency (solid line) and horizontal light transmittance (dashed line) of the semitransparent photovoltaic film versus α. The calculations considered not only the variation of sunlight incident angle θ [determined as a function of air mass (AM=cos⁻¹θ)], but also the change of global irradiance I_{G} according to the following experimentally determined formula (reference: Meinel A. B., and Meinel M. P., Applied Solar Energy, Addison Wesley Publishing Co., 1976):

I_{G}=1.1·1.353·0.7^{AM}^{^{0.678}}.

Note that the calculation results are applicable to the case that the surfaces of the first planar portions are curved. In the curved surface case, L values would rather be defined as the distance between the edge and the end of the first planar portions than be defined as the length of the first planar portions.

When α=0°, the values of (H-L)/H are substantially the fractions of the areas of the light transmitting opening to the total area of the flexible substrate. As the value of α increases, the horizontal light transmittance increases monotonically (the dashed lines), whereas the sunlight collection efficiency has a maximum value (the solid lines). The value of α corresponding to the maximum sunlight collection efficiency shifts toward zero as the value of L/H increases. When L/H=1, the sunlight is most efficiently collected at α=0°. It is noted that each design of the semitransparent photovoltaic film with a L/H value should consider two particular characteristic α values. One design benefits the semitransparent photovoltaic film by maximizing the sunlight collection efficiency while the improvement of light transmittance is limited; the other one maximize the light transmittance while keeping the value of sunlight collection efficiency the same as that at α=0°. Therefore, the design range of the semitransparent photovoltaic film of the disclosure as embodied herein includes these two characteristic points and the range within, unless other considerations are factored.

Referring to FIG. 10 and using L/H=0.7 as an example, when α=0 (named as conventional design in the later description), the sunlight collection efficiency is 70% and the light transmittance is 30%. When α=28.8 °, the maximum sunlight collection efficiency design is reached and shows the value of 87.1%, whereas the light transmittance is 38.7%. The increment of sunlight collection efficiency is as high as 17.1% compare to that of the conventional design. When α=75.6°, the maximum light transmittance design is reached and show the value of 82.6%, whereas the sunlight collection efficiency is still 70.7%. Without sacrificing the sunlight collection efficiency, the design of the semitransparent photovoltaic film allows the light transmittance to be increased by the increment of 52.6%. In other words, when L/H=0.7, a preferable design range of a lies approximately within 28.8° to 75.6°.

In light of the foregoing, according to the disclosure as embodied herein, the semitransparent photovoltaic film formed by an integrated flexible substrate absorbs most part of the sunlight for generating electricity, as well as transmits the relatively weak horizontal light and the light underneath allowing the human vision to see through it, thereby achieving the transparent visual effect. Having the characteristics of light weight, thinness, and flexibility, the semitransparent photovoltaic film disclosed herein can be designed as a flexible solar film capable of generating electricity and shielding the sunlight at the same time, thereby making the semitransparent photovoltaic film suitable for mass production and applicable on BIPV.

A semitransparent photovoltaic film is provided which is characterized by the properties of light weight, thinness and flexibility. It can be designed as a flexible solar film capable of generating electric energy and shielding the sunlight, which makes the film applicable to adhere on the outer window surface of modern building constructions.

The first support substrate of the photovoltaic film is required to be a light transmitting substrate if the first support substrate is disposed on a light receiving side of the semitransparent photovoltaic film. It is noted that transparency is defined herein as a visible light transmittance, whereas light transmitting is defined herein as a light transmittance according to the absorption spectrum of the photovoltaic cells.

In summary, the sunlight has its nature of high intensity at top-incident angle. On the other hand, collecting the horizontal light and the light underneath passing through a vertical object by eyes, people can see-through the vertical object and have a transparent visual experience. Therefore, the semitransparent photovoltaic film of the embodiment efficiently absorbs most part of the sunlight for generating electricity, as well as transmits the relatively weak horizontal light and the light underneath allowing the human vision to see through it, thereby achieving the transparent visual effect.

Although the embodiment has been described with reference to the above embodiments, it will be apparent to one of the ordinary skill in the art that modifications to the described embodiment may be made without departing from the spirit of the embodiment. Accordingly, the scope of the embodiment will be defined by the attached claims not by the above detailed descriptions.

What is claimed is:

1. A semitransparent photovoltaic film, comprising:
a flexible substrate integrating a plurality of first planar portions and a plurality of second planar portions, the second planar portions coupled to the first planar portions to form an angle; and
a plurality of photovoltaic cells formed on a surface of each of the first planar portions of the flexible substrate.

2. The semitransparent photovoltaic film as claimed in claim 1, wherein the flexible substrate comprises a light transmitting substrate or an opaque substrate.

3. The semitransparent photovoltaic film as claimed in claim 2, wherein the light transmitting substrate comprises plastic or glass.

4. The semitransparent photovoltaic film as claimed in claim 2, wherein the opaque substrate comprises a metal substrate or an opaque plastic substrate.

5. The semitransparent photovoltaic film as claimed in claim 1, wherein each of the second planar portions further comprises at least a light transmitting opening.

6. The semitransparent photovoltaic film as claimed in claim 1, wherein the photovoltaic cells comprises superstrate structure photovoltaic cells or substrate structure photovoltaic cells.

7. The semitransparent photovoltaic film as claimed in claim 1, wherein each of the photovoltaic cells comprises:
an opaque electrode;
a light transmitting electrode disposed on the opaque electrode; and
a photoelectric conversion cell disposed between the opaque electrode and the light transmitting electrode.

8. The semitransparent photovoltaic film as claimed in claim 7, further comprising a plurality of conductive lines formed on the flexible substrate, the conductive lines electrically coupled to the opaque electrode and/or the light transmitting electrode of each of the photovoltaic cells.

9. The semitransparent photovoltaic film as claimed in claim 8, wherein a part of the conductive lines is coupled to the light transmitting electrode of each of the photovoltaic cells, and another part of the conductive lines is coupled to the opaque electrode of each of the photovoltaic cells, so as to form a parallel configuration of electrodes having a same polarity.

10. The semitransparent photovoltaic film as claimed in claim 8, wherein the conductive lines are respectively coupled to the light transmitting electrode of one of the photovoltaic cells and to the opaque electrode of a next one of the photovoltaic cells, so as to form a serial configuration of electrodes having an opposite polarity.

11. The semitransparent photovoltaic film as claimed in claim 1, wherein each of the second planar portions has an adhesive surface.

12. The semitransparent photovoltaic film as claimed in claim 1, wherein a total thickness of the semitransparent photovoltaic film is between 1 mm and 15 mm.

13. The semitransparent photovoltaic film as claimed in claim 1, wherein a side of the first planar portions of the flexible substrate forms a coupling side for coupling to the second planar portions, the other sides of the first planar portions are separated from the second planar portions, and the first planar portions and the second planar portions form the angle by using the coupling side as an axis of separation.

14. The semitransparent photovoltaic film as claimed in claim 13, wherein the second planar portions comprises a rectangular frame structure having the first planar portions configured therein.

15. The semitransparent photovoltaic film as claimed in claim 14, wherein the first planar portions are rectangular.

16. A semitransparent photovoltaic film, comprising:
a first support substrate having a first zigzag surface;
a flexible substrate laminated on the first support substrate, wherein the flexible substrate integrates a plurality of first planar portions and a plurality of second planar portions, the second planar portions coupled to the first planar portions to form an angle, and the first planar portions are laminated on the first zigzag surface; and
a plurality of photovoltaic cells formed on a plurality of surfaces of the first planar portions of the flexible substrate.

17. The semitransparent photovoltaic film as claimed in claim 16, wherein the first support substrate is a light transmitting substrate.

18. The semitransparent photovoltaic film as claimed in claim 16, wherein the first support substrate has a first planar surface opposing the first zigzag surface.

19. The semitransparent photovoltaic film as claimed in claim 18, wherein the first planar surface of the first support substrate is an adhesive surface.

20. The semitransparent photovoltaic film as claimed in claim 16, wherein the first support substrate comprises soft materials.

21. The semitransparent photovoltaic film as claimed in claim 16, further comprising a second support substrate, wherein
the second support substrate has a second zigzag surface complementing the first zigzag surface of the first support substrate; and
the flexible substrate is laminated between the first zigzag surface of the first support substrate and the second zigzag surface of the second support substrate.

22. The semitransparent photovoltaic film as claimed in claim 21, wherein the second support substrate comprises soft materials.

23. The semitransparent photovoltaic film as claimed in claim 21, wherein one of the first support substrate or the second support substrate disposed on a light receiving surface of the semitransparent photovoltaic film is light transmitting.

24. The semitransparent photovoltaic film as claimed in claim 21, wherein the second support substrate has a second planar surface opposing the second zigzag surface.

25. The semitransparent photovoltaic film as claimed in claim 24, wherein the second planar surface of the second support substrate is an adhesive surface.

26. The semitransparent photovoltaic film as claimed in claim 16, wherein a total thickness of the semitransparent photovoltaic film is between 1 mm and 15 mm.

27. The semitransparent photovoltaic film as claimed in claim 16, wherein the flexible substrate comprises a light transmitting substrate or an opaque substrate.

28. The semitransparent photovoltaic film as claimed in claim 27, wherein the light transmitting substrate comprises plastic or glass.

29. The semitransparent photovoltaic film as claimed in claim 27, wherein the opaque substrate comprises a metal substrate or an opaque plastic substrate.

30. The semitransparent photovoltaic film as claimed in claim 16, wherein each of the second planar portions further comprises at least a light transmitting opening.

31. The semitransparent photovoltaic film as claimed in claim 16, wherein the photovoltaic cells comprises superstrate structure photovoltaic cells or substrate structure photovoltaic cells.

32. The semitransparent photovoltaic film as claimed in claim 16, wherein each of the photovoltaic cells comprises:
an opaque electrode;
a light transmitting electrode disposed on the opaque electrode; and
a photoelectric conversion cell disposed between the opaque electrode and the light transmitting electrode.

33. The semitransparent photovoltaic film as claimed in claim 32, further comprising a plurality of conductive lines formed on the flexible substrate, the conductive lines electrically coupled to the light transmitting electrode of each of the photovoltaic cells.

34. The semitransparent photovoltaic film as claimed in claim 16, wherein a side of the first planar portions of the flexible substrate forms a coupling side for coupling to the second planar portions, the other sides of the first planar portions are separated from the second planar portions, and the first planar portions and the second planar portions form the angle by using the coupling side as an axis of separation.

35. The semitransparent photovoltaic film as claimed in claim 34, wherein the second planar portions form a rectangular frame structure having the first planar portions configured therein.

36. The semitransparent photovoltaic film as claimed in claim 35, wherein the first planar portions are rectangular.
